(19) United States
(12) Patent Application Publication
(10) Pub. No.: US 2008/0164533 A1
(43) Pub. Date: Jul. 10, 2008

(54) Method of manufacturing a germanosilicide and a semiconductor device having the germanosilicide

(75) Inventors: Hyun-Deok Yang, Yongin-si (KR); Chang-wook Moon, Seoul (KR); Joong S. Jeon, Seongnam-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/000,494

(22) Filed: Dec. 13, 2007

(30) Foreign Application Priority Data
Dec. 29, 2006 (KR) 10-2006-0138859

(51) Int. Cl. H01L 29/49; H01L 21/44

(52) U.S. Cl. 257/382; 438/664; 257/E29.161

(57) ABSTRACT

Example embodiments relate to a method of manufacturing a germanosilicide and a semiconductor device having the germanosilicide. A method according to example embodiments may include providing a substrate having at least a portion formed of silicon germanium. A metal layer may be formed on the silicon germanium. A thermal process may be performed on the substrate at a relatively high pressure to form the germanosilicide.

### PRIORITY STATEMENT

This application claims priority under 35 U.S.C. §119 to Korean Patent Application No. 10-2006-0138859, filed on Dec. 29, 2006 in the Korean Intellectual Property Office (KIPO), the entire contents of which are incorporated herein by reference.

### BACKGROUND

1. Technical Field

Example embodiments relate to a method of manufacturing a germanosilicide and a semiconductor device having the germanosilicide.

2. Description of the Related Art

A larger scale integrated circuit (LSI) may involve numerous processes. Because of the processes, the resistances of metal lines connecting the source and the drain may increase. Thus, resistance values may increase, power consumption may increase, and signal transferring speed may be reduced. As a result, a relatively low sheet resistance may be required for a silicide formed by a thermal process on metals deposited on the source and the drain.

To improve the mobility of a transistor, a silicon germanium (SiGe) may be epitaxially grown on the source and drain to control compressive stress. A germanosilicide may be formed by depositing a metal on the silicon germanium and performing a thermal process. However, a thermal process may increase the resistance of the germanosilicide.

FIG. 1A shows a conventional stacked structure before thermal processing for forming a silicide, wherein a metal may be deposited on a Si substrate. FIG. 1B shows a conventional stacked structure before thermal processing for forming a germanosilicide, wherein a metal may be deposited on a SiGe substrate. FIG. 1C shows a conventional stacked structure before thermal processing for forming a silicide, wherein a metal may be deposited on a Si layer formed on a SiGe substrate.

The resistance of the germanosilicide formed by thermally processing the structure of FIG. 1B may be larger than that of the silicide formed by thermally processing the structure of FIG. 1A. To solve the above problem, as shown in FIG. 1C, a Si thin film may be grown on the SiGe substrate using an epitaxial growth method, a metal may be deposited thereon, and the stacked structure may be thermally processed to primarily form a silicide rather than a germanosilicide. Accordingly, a lower sheet resistance can be achieved, as shown in FIG. 2.

FIG. 2 illustrates the sheet resistance characteristics of the silicide and the germanosilicide formed on the conventional stacked structures in FIGS. 1A-1C by rapid thermal annealing (RTA). The horizontal axis represents the silicidation temperature, and the vertical axis represents the sheet resistance. Referring to FIG. 2, when Ni—Si_{0.8}Ge_{0.2} (stacked structure of FIG. 1B) is thermally processed, the sheet resistance may be higher than that of when Ni—Si (stacked structure of FIG. 1A) is thermally processed. However, when Ni—Si/Si_{0.8}Ge_{0.2} (stacked structure of FIG. 1C) is thermally processed, the sheet resistance may be similar to that of when Ni—Si (stacked structure of FIG. 1A) is thermally processed.

Thus, when a Si thin film is formed on silicon germanium using an epitaxial growth method and a metal layer is formed on the Si thin film, the generation of germanosilicide may be prevented during thermal processing and low sheet resistance may be achieved. However, because of the additional process of growing a Si thin film using an epitaxial growth method, the costs and time for fabricating semiconductor devices may increase and throughput may be reduced.

FIG. 3 illustrates the morphology of germanosilicide by performing a conventional RTA. The resistance of germanosilicide may be higher than that of silicide, because germanium may locally accumulate at an interface between the germanosilicide and the SiGe substrate. As a result, the interface may be relatively rough, as shown in FIG. 3. The accumulation of germanium may be greater at a higher temperature than at a lower temperature.

FIG. 4 shows conventional I-V characteristics of diodes with silicide and germanosilicide by performing a conventional RTA. The left graph of FIG. 4 shows the I-V characteristic of a silicide sample (NiSi) formed by providing a nickel (Ni) layer on a Si substrate and performing a thermal process. The right graph of FIG. 4 shows the I-V characteristic of a germanosilicide sample (NiSiGe) formed by providing a Ni layer on a SiGe substrate and performing a thermal process. The leakage current of a diode with germanosilicide may increase due to higher roughness and interface charges of germanosilicide than those of silicide, as shown in FIG. 4.

### SUMMARY

Example embodiments relate to a method of manufacturing a germanosilicide and a semiconductor device having the germanosilicide, wherein the roughness of an interface between the germanosilicide and a substrate may be improved and sheet resistance may be reduced. A method of manufacturing a germanosilicide according to example embodiments may include providing a substrate having at least a portion formed of silicon germanium. A metal layer may be formed on the silicon germanium. A thermal process may be performed on the stacked structure at a relatively high pressure (above atmospheric pressure) to form the germanosilicide.

The thermal process may be performed at a relatively high pressure of about 3 atm to about 100 atm. For example, the thermal process may be performed at a pressure of about 10 atm. The thermal process may be performed at a temperature of about 100° C. to about 600° C. For example, the thermal process may be performed at a temperature of about 300° C. The thermal process may be a germanosilicidation process. The metal layer may be a single layer or a stacked structure including a plurality of layers. The metal layer may be formed of one element or an alloy of a plurality of elements. The substrate may be a silicon germanium substrate (Si₁₋ₓGeₓ; 0<x<1). The substrate may include a doping region, and the metal layer may be formed on the doping region. The substrate may be a silicon substrate. The portion of the substrate formed of silicon germanium may be doped with impurities.

A semiconductor device according to example embodiments may include a substrate having a source region and a drain region. A germanosilicide may be provided on the source and drain regions. The germanosilicide may be formed by preparing the substrate such that at least a portion thereof is formed of silicon germanium. A metal layer may be formed on the silicon germanium. A thermal process may be performed on the substrate at a relatively high pressure to form the germanosilicide.

### BRIEF DESCRIPTION OF THE DRAWINGS

FIG. 1A shows a conventional stacked structure before thermal processing for forming a silicide, wherein a metal layer is deposited on a silicon (Si) substrate.

FIG. 1B shows a conventional stacked structure before thermal processing for forming a germanosilicide, wherein a metal is deposited on a SiGe substrate.

FIG. 1C shows a conventional stacked structure before thermal processing for forming a silicide, wherein a metal is deposited on a Si layer formed on a SiGe substrate.

FIG. 2 shows sheet resistance characteristics of the silicide and the germanosilicide formed by performing a conventional rapid thermal annealing (RTA) process on the conventional stacked structures of FIGS. 1A through 1C.

FIG. 3 illustrates the morphology of germanosilicide formed by performing a conventional RTA.

FIG. 4 shows I-V characteristics of diodes with silicide and germanosilicide by performing a conventional RTA.

FIGS. 5A and 5B schematically illustrate a method of manufacturing a germanosilicide according to example embodiments.

FIGS. 6A and 6B each show the sheet resistance characteristics of two samples, wherein one sample is obtained by depositing Pt on a silicon germanium (SiGe) substrate and performing a conventional RTA process for two minutes, and the other sample is obtained by depositing Pt on a SiGe substrate and performing a relatively high pressure annealing (HPA) process according to example embodiments for two minutes at a pressure of 10 atm. FIG. 6A shows the sheet resistances of the two samples on a log scale. FIG. 6B shows the sheet resistances of the two samples on a linear scale.

FIGS. 7A and 7B are a transmission electron microscope (TEM) image and an energy dispersive x-ray spectroscopy (EDS) result, respectively, of a sample processed by a conventional RTA at a temperature of 300° C. and wet-etched.

FIG. 8A is a TEM image of a sample processed by a conventional RTA at a temperature of 600° C.

FIG. 8B is a TEM image of a sample processed by a HPA according to example embodiments at a temperature of 300° C. and a pressure of 10 atm.

FIG. 9 shows a semiconductor device according to example embodiments, wherein the semiconductor device includes germanosilicide formed by a relatively high pressure thermal process according to example embodiments.

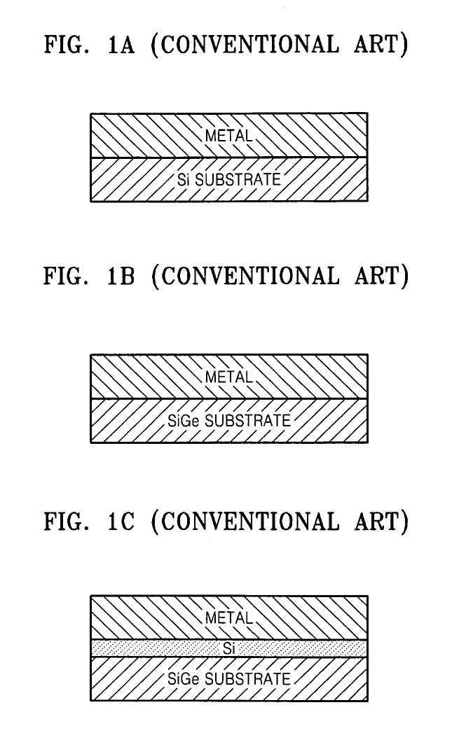

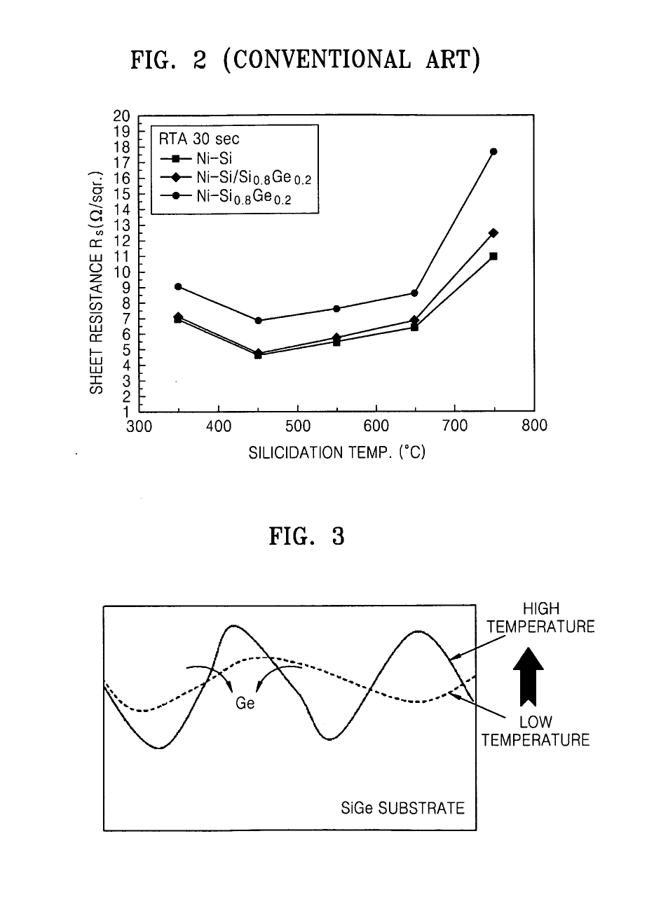

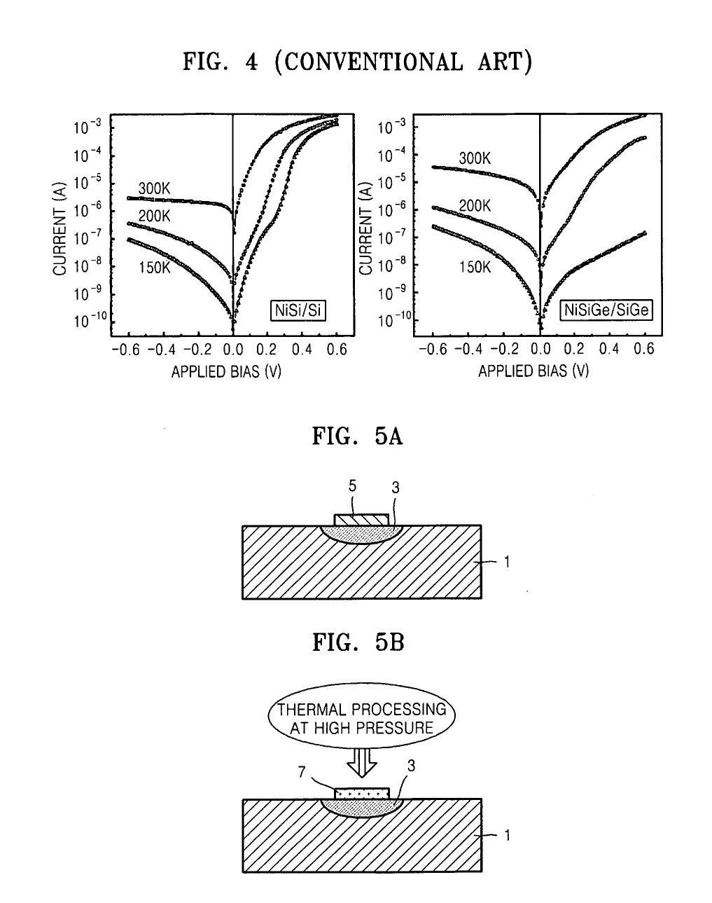

### DETAILED DESCRIPTION OF EXAMPLE EMBODIMENTS

It will be understood that when an element or layer is referred to as being “on”, “connected to”, “coupled to”, or “covering” another element or layer, it may be directly on, connected to, coupled to, or covering the other element or layer or intervening elements or layers may be present. In contrast, when an element is referred to as being “directly on,” “directly connected to” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

An annealing process according to example embodiments may be performed at a relatively high pressure to reduce the roughness of an interface between a germanosilicide and a substrate and to reduce the sheet resistance of the interface. FIGS. 5A and 5B schematically illustrate a method of manufacturing a germanosilicide according to example embodiments. Referring to FIG. 5A, a substrate 1 may be prepared so as to have at least a portion 3 thereof formed of silicon germanium. A metal layer 5 may be formed on the portion 3 of the substrate formed of silicon germanium.

The substrate 1 may be a silicon germanium substrate (Si₁₋ₓGeₓ; 0<x<1) or a silicon substrate. Silicon germanium may be epitaxially grown on a portion 3 of the substrate 1. The portion 3 of the substrate 1 may be a source, a drain or an upper surface of a gate electrode. The metal layer 5 may be a single layer or a stacked structure including a plurality of layers. The metal layer 5 may be formed of one element or an alloy of a plurality of elements. For example, the metal layer 5 may be formed of Sc, Ti, V, Cr, Co, Ni, Cu, Y, Zr, Nb, Mo, Ru, Rh, Pd, Hf, Ta, W, Re, Ir, Pt, La, Sm, Gd, Dy, Er, Yb, TiN, or a combination thereof.

Referring to FIG. 5B, the metal layer 5 may be thermally processed at a relatively high pressure (above atmospheric pressure) to form germanosilicide 7 on the substrate 1. The thermal process may be performed at a relatively high pressure of about 3 atm to about 100 atm. For example, the thermal process may be performed at a pressure of about 10 atm or higher. In addition, the thermal process may be performed at a temperature of about 100° C. to about 600° C. For example, the thermal process may be performed at a temperature of about 300° C. The thermal process may be a germanosilicidation, wherein an object may be heated at a temperature and a pressure to allow sufficient reaction between the metal layer 5 and the substrate 1. Any portion the metal layer 5 not having germanosilicide 7 formed thereon may be optionally removed by wet etching.

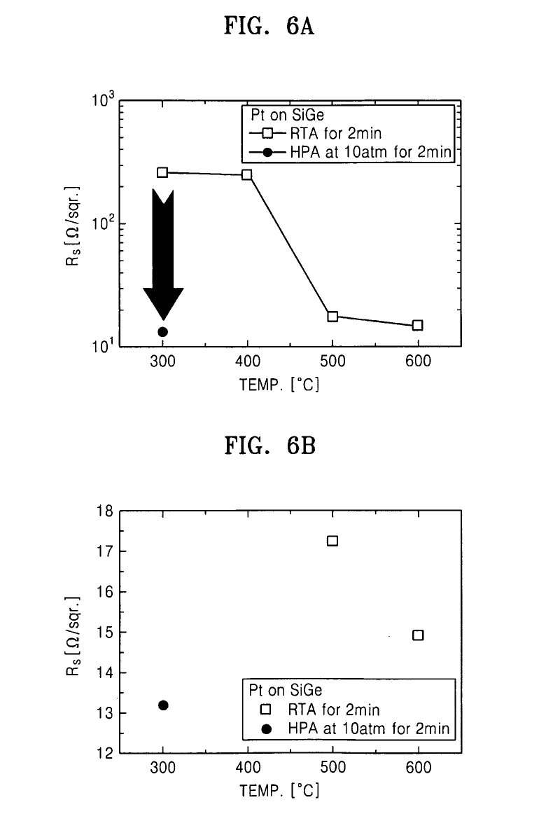

FIGS. 6A and 6B each show the sheet resistance characteristics of two samples, wherein one sample is obtained by depositing Pt on a silicon germanium (SiGe) substrate and performing a conventional RTA process for two minutes, and the other sample is obtained by depositing Pt on a SiGe substrate and performing a relatively high pressure annealing (HPA) process according to example embodiments for two minutes at a pressure of 10 atm. FIG. 6A shows the sheet resistance characteristics of the germanosilicide formed by RTA and HPA on a log scale, and FIG. 6B shows the sheet resistance characteristics of the germanosilicide formed by RTA and HPA on a linear scale.

Referring to FIGS. 6A and 6B, the sample obtained using a conventional RTA process may show a relatively large resistance at lower temperatures, because temperatures of about 400° C. or less may not be conducive to the formation of germanosilicide (e.g., PtSiGe) in a conventional RTA process. Rather, a conventional RTA process may require a relatively high temperature to form germanosilicide. As shown in FIGS. 6A and 6B, the sheet resistance of the sample obtained using a conventional RTA process is lowest at a temperature of about 600° C. In contrast, the sheet resistance of the sample obtained with the HPA process according to example embodiments may be lower than that of the conventional RTA process and may be obtained at a relatively low temperature (e.g., about 300° C.) within a short period of time. Thus, germanosilicide may be formed at a relatively low temperature (e.g., 300° C.) with the HPA process according to example embodiments.

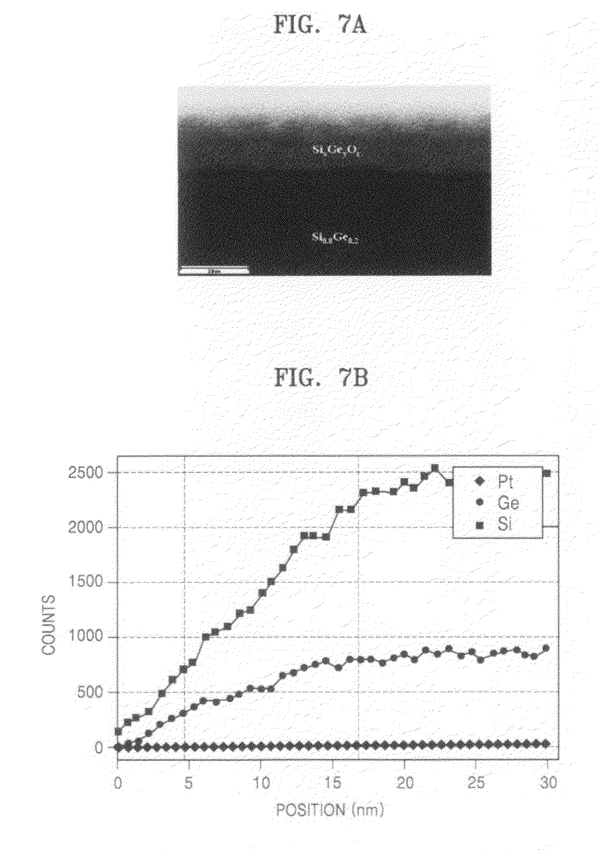

FIGS. 7A and 7B show a transmission electron microscope (TEM) image and an energy dispersive x-ray spectroscopy (EDS) result, respectively, of a sample obtained with a conventional RTA process at a temperature of about 300° C. and a wet-etching process. As discussed above and as shown in FIGS. 7A and 7B, temperatures of about 400° C. or less may not be conducive to the formation of germanosilicide (e.g., PtSiGe) in a conventional RTA process.

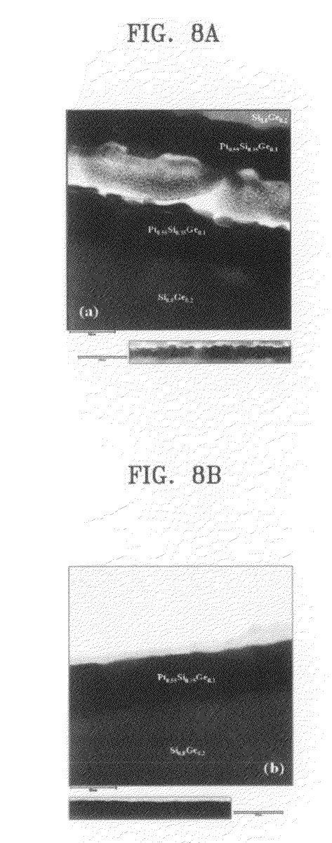

FIG. 8A shows a TEM image of a sample obtained with a conventional RTA process at a temperature of about 600° C. FIG. 8B shows a TEM image of a sample obtained with a HPA process according to example embodiments at a temperature of about 300° C. and about 10 atm. In FIG. 8A, the germanosilicide (PtSiGe) may be formed when the conventional RTA process is performed at a temperature of about 600° C. However, as shown in FIG. 8A, the interface and surface morphology of the germanosilicide may be relatively rough.

FIG. 8B shows the germanosilicide (PtSiGe) formed by a HPA process according to example embodiments at a temperature of about 300° C. As shown in FIG. 8B, the interface and surface morphology of the germanosilicide may be improved, thus indicating that the local diffusion of germanium (Ge) may have been reduced or prevented during the formation of the germanosilicide.

As described above, a thermal process performed at a relatively high pressure may reduce the roughness of the interface between the germanosilicide and the substrate and decrease the sheet resistance of the germanosilicide. Additionally, the thermal process according to example embodiments may involve a relatively low temperature when compared to a conventional RTA process. Therefore, when germanosilicide is formed on the source and drain using the above method according to example embodiments, the resistance values of metal lines connected to the source and drain in a transistor may be reduced, and a higher speed transistor utilizing the germanosilicide may be realized.

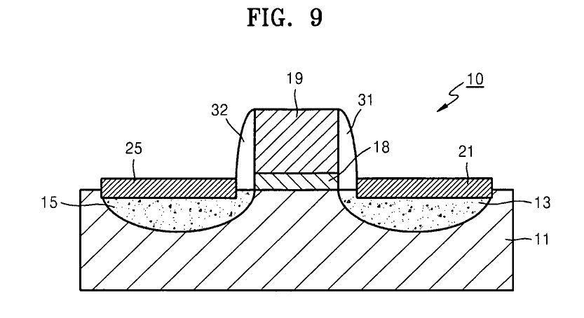

A semiconductor device utilizing a germanosilicide formed by the HPA process according to example embodiments may have a transistor structure as shown in FIG. 9. Referring to FIG. 9, the semiconductor device according to example embodiments may include a transistor 10. The transistor 10 may include a source region 13 and a drain region 15 formed on a substrate 11. A gate insulating layer 18 may be formed on the substrate 11. A gate electrode 19 may be formed on the gate dielectric 18. The gate insulating layer 18 and gate electrode 19 may be surrounded by sidewalls 31 and 32. Germanosilicide members 21 and 25 may be formed on the source and drain regions 13 and 15, respectively, by a HPA process according to example embodiments.

The substrate 11 may be a silicon substrate or a silicon germanium substrate (Si₁₋ₓGeₓ; 0<x<1). The source and drain regions 13 and 15 may be formed of silicon germanium (Si₁₋ₓGeₓ; 0<x<1). For example, the silicon germanium may be epitaxially grown in the source and drain regions 13 and 15 on the substrate 11. The source and drain regions 13 and 15 may also be doped with predetermined impurities. A metal layer may be provided on the surface of semiconductor device 10, and a HPA process according to example embodiments may be performed to form the germanosilicide members 21 and 25 on the first and second doping regions 13 and 15, wherein the germanosilicide members 21 and 25 have relatively smooth interface and low sheet resistances.

Silicon germanium (SiGe) epitaxially grown on a source and drain may adjust compressive stress so as to realize a higher speed transistor by improving mobility. A conventional higher speed transistor may require an epitaxial silicon (Si) thin film on the SiGe before silicidation to achieve low sheet resistance. However, a method of manufacturing a germanosilicide according to example embodiments may provide a low sheet resistance without the additional Si thin film required by conventional methods. Thus, characteristics of the device as well as manufacturing throughput may be improved.

Although the germanosilicide has been described above as being formed on the source and drain regions 13 and 15 of the transistor 10, example embodiments are not limited thereto. For example, the germanosilicide manufacturing method according to example embodiments may be utilized to form metal lines (not shown) of the gate electrode 19 in the transistor 10. In addition, the method according to example embodiments may be applied to a variety of devices requiring the improved interface and surface profile of the germanosilicide so as to reduce sheet resistance.

A semiconductor device having a germanosilicide manufactured using the HPA process according to example embodiments may be formed into a transistor for use as a logic unit cell in microprocessors, digital signal processors, center processing units, and logic devices, which may be larger scale integration (LSI) logic circuits and devices requiring lower sheet resistance. As a result, a transistor according to example embodiments may provide higher speeds and lower power consumption.

As described above, when a germanosilicide is formed using the HPA process according to example embodiments, a lower sheet resistance may be obtained within a short period of time at a lower temperature when compared to a conventional RTA process. In addition, the roughness of the interface between the germanosilicide and the SiGe substrate may be improved, and consequently, the interface charges and the leakage current may be reduced, thus improving characteristics of the device.

While example embodiments have been disclosed herein, it should be understood that other variations may be possible. Such variations are not to be regarded as a departure from the spirit and scope of example embodiments of the present disclosure, and all such modifications as would be obvious to one skilled in the art are intended to be included within the scope of the following claims.

What is claimed is:

1. A method of manufacturing a germanosilicide, comprising:
providing a substrate having at least a portion formed of silicon germanium;
forming a metal layer on the silicon germanium; and
performing a thermal process on the substrate at a high pressure to form the germanosilicide.

2. The method of claim 1, wherein the thermal process is performed at a pressure of about 3 atm to about 100 atm.

3. The method of claim 2, wherein the thermal process is performed at a pressure of about 10 atm.

4. The method of claim 1, wherein the thermal process is performed at a temperature of about 100° C. to about 600° C.

5. The method of claim 4, wherein the thermal process is performed at a temperature of about 300° C.

6. The method of claim 1, wherein the thermal process is a germanosilicidation process.

7. The method of claim 1, wherein the metal layer is a single layer or a stacked structure including a plurality of layers.

8. The method of claim 1, wherein the metal layer is formed of one element or an alloy of a plurality of elements.

9. The method of claim 1, wherein the substrate is a silicon germanium substrate.

10. The method of claim 9, wherein the substrate includes a doping region, and the metal layer is formed on the doping region.

11. The method of claim 1; wherein the substrate is a silicon substrate.

12. The method of claim 11, wherein the portion of the substrate formed of silicon germanium is doped with impurities.

13. A semiconductor device comprising:
a substrate having a source region and a drain region;
a gate dielectric provided on the substrate;
a gate electrode provided on the gate dielectric; and
a germanosilicide provided on the source and drain regions,
wherein the germanosilicide is formed by preparing the substrate such that at least a portion thereof is formed of silicon germanium; forming a metal layer on the silicon germanium; and performing a thermal process on the substrate at a high pressure to form the germanosilicide.

14. The semiconductor device of claim 13, wherein the thermal process is performed at a pressure of about 3 atm to about 100 atm.

15. The semiconductor device of claim 13, wherein the thermal process is performed at a temperature of about 100° C. to about 600° C.

16. The semiconductor device of claim 13, wherein the thermal process is a germanosilicidation process.

17. The semiconductor device of claim 13, wherein the metal layer is a single layer or a stacked structure including a plurality of layers.

18. The semiconductor device of claim 13, wherein the metal layer is formed of one element or an alloy of a plurality of elements.

19. The semiconductor device of claim 13, wherein the substrate is a silicon substrate, and the source and drain regions include silicon germanium grown with an epitaxial growth method.

20. The semiconductor device of claim 13, wherein the source and drain regions are doped with impurity elements.

21. The semiconductor device of claim 13, wherein the substrate is a silicon germanium substrate.
